(19) United States
(12) Patent Application Publication
(10) Pub. No.: US 2025/0267824 A1
(43) Pub. Date: Aug. 21, 2025

(54) PACKAGED POWER INVERTER

(71) Applicant: Caterpillar Inc., Peoria, IL (US)

(72) Inventor: Eric M. ANDRIS, Dunlap, IL (US)

(73) Assignee: Caterpillar Inc., Peoria, IL (US)

(21) Appl. No.: 18/444,004

(22) Filed: Feb. 16, 2024

(51) Int. Cl. H05K 7/20; H02M 7/00

(52) U.S. Cl. CPC H05K 7/209; H02M 7/003; H05K 7/20927

(57) ABSTRACT

A packaged power inverter including a cylindrical outer housing having a central longitudinal axis, a heatsink core located within the housing and having a longitudinal axis aligned with the longitudinal axis of the outer housing and a plurality of outer planar surface portions. The packaged power inverter further includes a plurality of electronic modules each being coupled to one of the plurality of planar surface portions. A plurality of AC bus bars are coupled to one of the plurality of planar surface portions. A plurality of capacitors and DC bus bars located within the outer housing.

### TECHNICAL FIELD

The present disclosure relates generally to a power inverter, and more particularly, to a packaged power inverter.

### BACKGROUND

A large driver of cost in power inverters systems is the packaging of the system. Often the packaging requires a complex and difficult assembly process requiring specialized parts. The packaging may also drive the layout of the internal components, which may lead to non-uniform power and heat distribution that may interfere with performance and make accessing the internal components difficult.

Commonly, power inverter system packaging is non-modular, which may limit a system's ability to readily combine with multiple different power systems, such as electric motors, power generators, and other packaged power inverters. The non-modular designs may also limit the scalability of power inverter systems by limiting access and preventing the internal components from being interchanged.

U.S. Pat. No. 6,501,653 B1 (the '653 reference) describes a multiphase converter which contains semiconductor power components and a capacitor on a support containing cooling devices. The components of the multiphase converter are arranged in a compact configuration, in which the support containing the cooling device is configured as a hollow body, the capacitor is insertable in its interior, and the semiconductor power components are arranged on its outer side, where the height of the hollow body corresponds substantially to the height of the necessary capacitor. For a three-phase converter, the hollow body may be in the shape of a hexagon on the outer side, so that an overall shape approximating a cylinder is created, and a cylindrical cover protects everything and makes a compact component available. The '653reference does not appreciate the need for variably sized capacitors, nor does the '653 reference recognize the use of an enclosure to secure an inner heatsink. The '653 is also silent as to sealed compartments that can accept a number of connections at a multitude of directions.

The modular packaged power inverter of the present disclosure may solve one or more of the problems set forth above and/or other problems in the art. The scope of the current disclosure, however, is defined by the attached claims, and not by the ability to solve any specific problem.

### SUMMARY

In one aspect, the disclosure relates to a packaged power inverter including a cylindrical outer housing having a central longitudinal axis, and a heatsink core located within the housing and having a longitudinal axis aligned with the longitudinal axis of the outer housing and a plurality of outer planar surface portions. The packaged power inverter further includes a plurality of electronic modules, each being coupled to one of the plurality of planar surface portions. The packaged power inverter further includes a plurality of AC bus bars, each being coupled to one of the plurality of planar surface portions. The packaged power inverter further includes a plurality of capacitors located within the outer housing, and a plurality of DC bus bars located within the outer housing.

In another aspect, the disclosure described herein relates to a packaged power inverter, including a cylindrical outer housing having a central longitudinal axis, and a heatsink core located within the housing and having a longitudinal axis aligned with the longitudinal axis of the outer housing and a plurality of outer planar surface portions. The packaged power inverter further includes a plurality of electronic modules, each being coupled to one of the plurality of planar surface portions. The packaged power inverter further includes a plurality of AC bus bars, each associated with one of the plurality of electronic modules, and located radially outside a respective electronic module. The packaged power inverter further includes a plurality of capacitors located within the outer housing, a plurality of DC bus bars located within the outer housing, and a DC bus bar located axially between the heatsink core and the plurality of capacitors.

In another aspect, the techniques described herein relate to a method of assembling a packaged power inverter, the method including: coupling a heat sink core to a first endplate; coupling one or more electronic modules to respective planar sides of the heat sink core; coupling AC bus bars and DC bus bars to the electronic modules; coupling another DC bus bar to one or more capacitors to form an assembly; coupling the DC bus bar within the assembly to the DC bus bars coupled to the electronics modules; placing a cylindrical housing wall upon the first endplate so as to encompass the heat sink core, the one or more electronics modules, the AC bus bars, the DC bus bars, and the assembly; and coupling a top plate to the heat sink core such that the top plate compresses the cylindrical housing wall against the first endplate.

### BRIEF DESCRIPTION OF THE DRAWINGS

The accompanying drawings, which are incorporated in and constitute a part of this specification, illustrate various exemplary embodiments and together with the description, serve to explain the principles of the disclosed embodiments.

FIG. 1 is a front perspective view of a packaged power inverter according to aspects of the disclosure.

FIG. 2 is an exploded view of the packaged power inverter of FIG. 1.

FIG. 3 is a cross sectional view of the packaged power inverter of FIG. 1.

FIG. 4 is a close up side view of the packaged power inverter of FIG. 1.

FIG. 5 is a cross sectional view of the packaged power inverter of FIG. 1

FIG. 6 provides a flowchart depicting current transfer through a packaged power inverter, according to aspects of the present disclosure.

FIG. 7 provides a flowchart depicting a method of assembling a packaged power inverter, according to aspects of the present disclosure

### DETAILED DESCRIPTION

Both the foregoing general description and the following detailed description are exemplary and explanatory only and are not restrictive of the features, as claimed. As used herein, the terms “comprises,” “comprising,” “has,” “having,” “includes,” “including,” or other variations thereof, are intended to cover a non-exclusive inclusion such that a process, method, article, or apparatus that comprises a list of elements does not include only those elements, but may include other elements not expressly listed or inherent to such a process, method, article, or apparatus. In this disclosure, unless stated otherwise, relative terms, such as, for example, “about,” “substantially,” and “approximately” are used to indicate a possible variation of ±10% in the stated value.

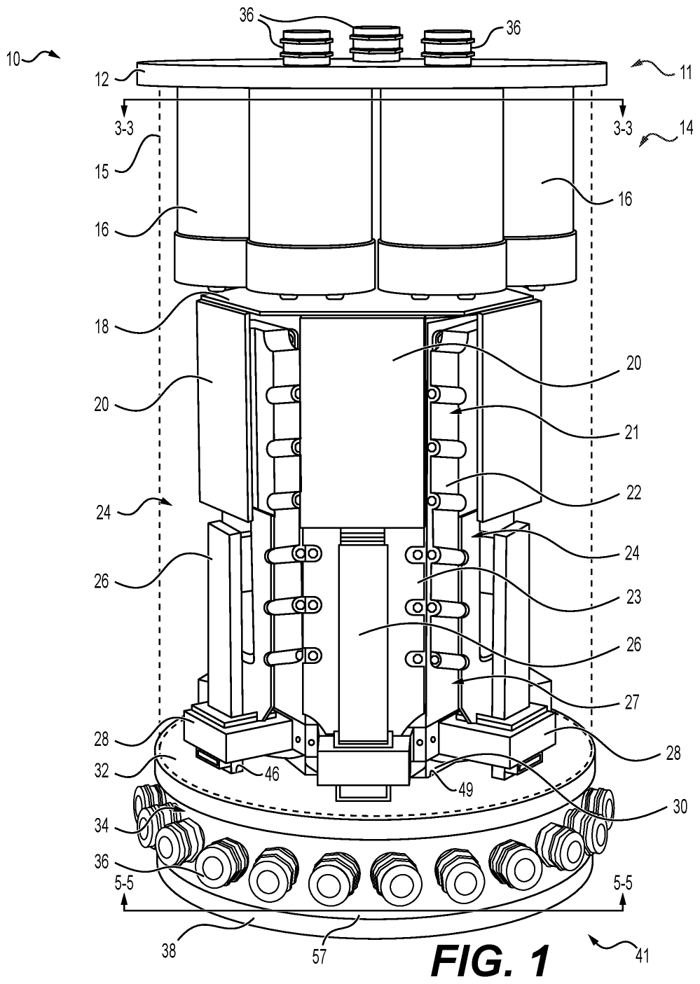

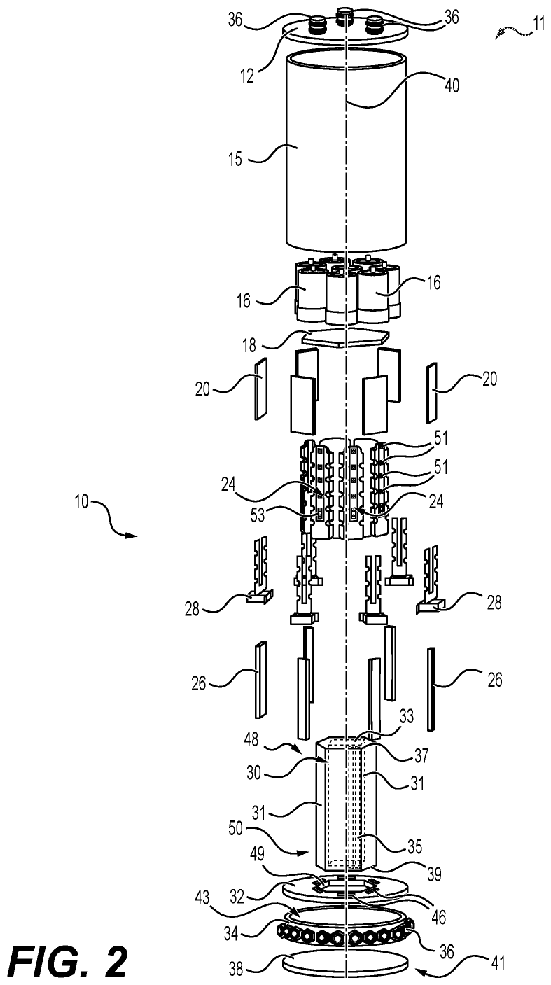

FIG. 1 and FIG. 2 are a front perspective view and an exploded view, respectively, of a packaged power inverter 10, according to an example embodiment. As will be explained in more detail below, components of the packaged power inverter 10 may transform an input alternating current (AC current) having an input waveform to an output AC current having an output waveform. Within the packaged power inverter 10, the input AC current may be transformed to a direct current (DC current) by power electronic devices acting as power rectifiers before being transformed to the output AC current having a desired output waveform by power electronic components acting as power inverters. Although referenced as a power inverter, those in the art will understand that the packaged power inverter 10 may function as both an inverter and a rectifier.

Referring to FIG. 1 and FIG. 2, the packaged power inverter 10, forms a generally cylindrical shape including a central longitudinal axis 40 extending between a first, top end 11 and a second, bottom end 41. The packaged power inverter 10 may further include a cylindrical outer housing 14, a centrally-located heatsink core 30, a plurality of electronic modules 24 coupled radially outside the heatsink core 30, a plurality of AC bus bars 26 coupled radially outside the electronic modules 24, and a plurality of DC bus bars, which may include vertical DC bus bars 20 also located radially outside the electronic modules and a horizontal DC bus bar 18 above the heatsink core 30. The packaged power inverter 10 further includes a plurality of capacitors 16 above the horizontal DC bus bar 18, and a cable manifold 34 located below the heatsink core 30. As shown in FIGS. 1 and 2, a plurality of similar components may additionally be disposed circumferentially about the central longitudinal axis 40 as well, and it is to be understood that the description of one component herein equally applies to the other similar components.

The cylindrical outer housing 14 may further comprise a cylindrical housing wall 15 (shown in dashed lines in FIG. 1), a first, or top endplate 12 at the top end 11 of the packaged power inverter 10, and a second, or bottom endplate 32 at the bottom end 41 of the packaged power inverter 10. The top endplate 12 may be bolted to the heat sink core 30, or attached in any other appropriate manner, so as to compress the cylindrical outer housing wall 15 onto the bottom endplate 32. The top endplate 12 may be may optionally include one or more cable glands 36. The cylindrical housing wall 15 may be made from a single Aluminum tube, and formed by an extrusion process. In other embodiments, the cylindrical housing wall 15 may be formed by a different process or a different material. The top endplate 12 and the bottom endplate 32 may also be made from aluminum, or another suitable material, and may be formed by any appropriate process.

The dimensions of the cylindrical housing wall 15 may vary based on the desired size or capacity of the packaged power inverter 10. The size or capacity of the packaged power inverter 10 may dictate the size of the heatsink core 30, as well as the number and size of the plurality of electronic modules 24, the plurality of capacitors 16, or other components of the packaged power inverter 10. In embodiments shown in FIG. 1. and FIG. 2, the cylindrical housing wall 15 may be, for example, between 8 inches and 16 inches in outer diameter. In particular embodiments, the cylindrical housing wall 15 may be 8 inches in diameter, 12 inches in diameter, or 16 inches in diameter. In other embodiments, the housing wall 15 may have a different diameter. The length of the cylindrical housing wall 15 may be between 12 and 36 inches. In particular embodiments, the cylindrical housing wall 15 may be 12 inches in length or 24 inches in length. In other embodiments cylindrical housing wall 15 may have a different length. The cylindrical housing wall 15 may have a thickness between 1 millimeter and 10 millimeters. In particular embodiments, the cylindrical housing wall 15 may have a thickness of 6 millimeters. In other embodiments the cylindrical housing wall 15 may have different wall thickness values.

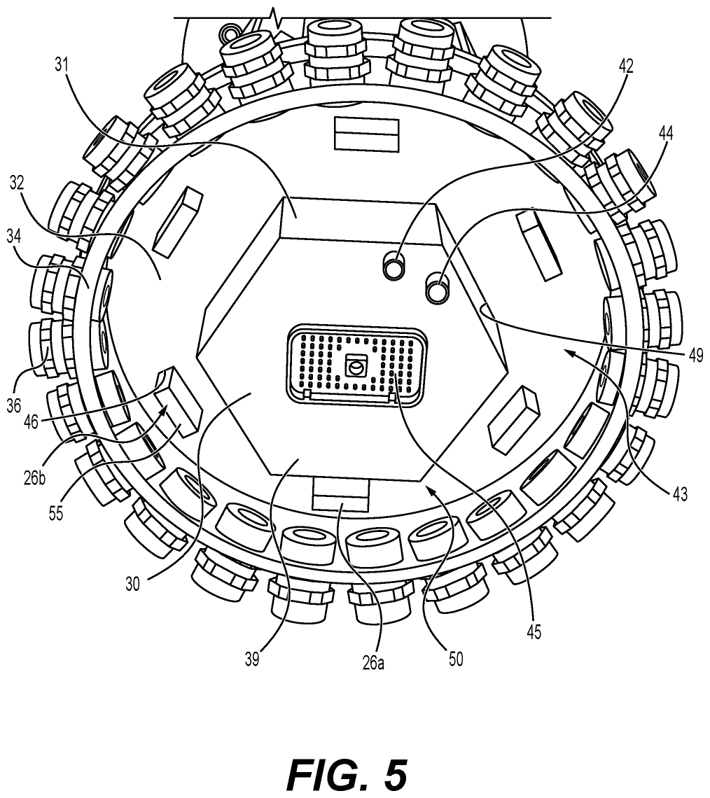

The heatsink core 30 may have a bottom end 50 connected to the bottom endplate 32 and a top end 48 opposite the bottom end 50. The bottom end 50 may comprise a bottom face 39, and the top end 48 may comprise a top face 37. The bottom face 39 and the top face 37 may be oriented normal to a longitudinal axis aligned with the central longitudinal axis 40. As best shown in FIG. 5, the bottom end 50 may extend beyond the bottom endplate 32 in a direction opposite the top end 48 through an opening 49 in bottom plate 32. In other embodiments, the bottom face 39 may be aligned or flush with the bottom plate 32. The heatsink core 30 may be rigidly attached to endplate 32 using bolts, screws, pins, or other fasteners. In other embodiments, the heatsink core 30 may be welded or glued to the bottom endplate 32. The heatsink core 30 may be a monolithic (i.e., single) component formed of extruded aluminum. In other embodiments, the heatsink may be formed by a different process or a different material, and may be made from multiple pieces.

As best seen in FIG. 2, the heatsink core 30 may have a length extending along the central longitudinal axis 40 and have a horizontal cross-section (normal to the central longitudinal axis 40) forming a hexagon (six straight sides). Outer planar surface portions, or outer planar sides 31 extend along the length between the bottom face 39 and the top face 37, and may be radially oriented about a longitudinal axis aligned with the central longitudinal axis 40. Thus, as best shown in FIG. 2, heatsink core 30 forms six planar sides 31. In further embodiments, the heatsink core 30 may have a triangular cross-section forming three planar sides 31, an octagonal cross-section forming eight planar sides 31, or an enneagonal cross-section forming nine planar sides 31. In other embodiments, the heatsink core 30 may have a different number of planar sides 31 that form a different shape.

The heatsink core 30 may be hollow, so as to form a central opening 33 radially interior to the planar sides 31. The central opening 33 in heatsink core 30 may extend along the central longitudinal axis 40 and may extend completely through heatsink core 30. A partial central opening 33, not extending completely through the heatsink core 30 is also contemplated. The walls of the heatsink core 30 may include internal longitudinal passages 35 circumferentially around heatsink core 30 (only two shown in dashed lines in FIG. 2) for conveying cooling fluid, such as liquid coolant in the form of water. Control electronics, such as controllers, sensors, and wiring for controlling and communicating with the electronics modules 24 may also be placed within the central opening 33.

The electronics modules 24, AC bus bars 26, and vertical DC bus bars 20 may be symmetrically organized about the heat sink core 30 and aligned with a respective one of the planar sides 31. The electronic modules 24 may comprise insulated-gate bipolar transistor modules (IGBT modules) 22 and a gate drivers 23. The IGBT modules 22 may be directly coupled to the one of the plurality of planar sides 31 of the heatsink core 30 such that IGBT modules contact the planar sides 31, and the gate drivers 23 may be coupled to the IGBT modules 22 at a radially outer surface of the IGBT modules 22. In some embodiments, the IGBT modules 22 may be coupled to the planar sides 31 of the heatsink core 30 using bolts (as shown), screws, pins or other fasteners. In other embodiments, the IGBT modules 22 may be welded or glued to the planar sides 31 of the heatsink core 30. In further embodiments, the IGBT modules 22 may be coupled to planar sides 31 of the heatsink core 30 using another suitable means, and the IGBT modules 22 may be indirectly coupled to the planar sides 31 such that there is a gap or other component between the IGBT modules 22 and the planar sides 31.

IGBT modules 22 may have a first set of terminals, or AC terminals 53, located on the radially outer surface at a first, AC end 27 of the electronic modules 24 nearest the bottom end 41 of the of the packaged power inverter 10, and a second set of terminals, or DC terminals 51, located on the radially outer surface at a second DC end 21 of the electronic modules 24 nearest the top end 11 of the packaged power inverter 10.

Each of the plurality of AC bus bars 26 may be rectangular in shape, with a lengthwise dimension extending parallel to the central longitudinal axis 40 of the packaged power inverter 10. The AC bus bars 26 may overlap and directly couple to a radially outer portion of the AC end 27 of the electronic modules 24 so as to engage the AC terminals 53, and may extend through holes 46 in the bottom plate 32 of the cylindrical housing 14. As shown in FIG. 5, a bottom end portion 55 of the AC bus bars extend into the cable manifold 34.

Each of the plurality of the vertical DC bus bars 20 may be rectangular in shape with a lengthwise dimension extending parallel to the central longitudinal axis 40 of the packaged power inverter 10. The vertical DC bus bars 20 may overlap and couple to a radially outer portion of the DC end 21 of the electronic modules 24 and extend towards the top endplate 12 until reaching and connecting to the horizontal DC bus bar 18.

The horizontal DC bus bar 18 may be a plate within the cylindrical outer housing 14 connected to the vertical DC bus bars 20, and oriented normal to the central longitudinal axis 40. The horizontal DC bus bar 18 may be flat or plate-shaped and have a geometric outer shape, such as a circular shape or a hexagon shape. In some embodiments, the horizontal DC bus bar may be shaped so as to match the number of sides of the heat sink 30. For example, as shown in FIGS. 1-2, both the horizontal DC bus bar 18 and the heat sink core 30 may be hexagonal to match the number of sides of the heatsink core 30. The horizontal DC bus bar 18 may be electrically coupled to the vertical DC bus bars 20 via, for example, bolts, clamps, or welds. In some embodiments, conductive tape may be used to electrically connect the horizontal DC bus bar 18 to the vertical DC bus bars 20. In particular embodiments, the horizontal DC bus bar 18 and the vertical DC bus bar 20 may be integrally formed. Additional horizontal bus bars 18 may be added so as to provide parallel connections to the positive and negative terminals of the capacitors 16.

The plurality of capacitors 16 are located axially between the horizontal DC bus bar 18 and the top endplate 12, such that the horizontal DC bus bar 18 may axially separate the heatsink core 30 from the plurality of capacitors 16. The capacitors 16 may be cylindrical film capacitors with a longitudinal axis oriented parallel to the central longitudinal axis 40. In other embodiments, different shapes and types of capacitors may be used. The top endplate 12 may fix the capacitors 16 on to the horizontal DC bus bar 18 so as to restrain the motion of the capacitors 16 along the central longitudinal axis 40. The capacitors 16 may be coupled to the horizontal DC bus bar 18 by screwing the terminals of the capacitors 16 into corresponding holes (not shown) within the horizontal DC bus bar 18, or in any other appropriate manner.

The cable manifold 34 may include an outer cylindrical wall 57 extending from the bottom endplate 32 in a direction away from the heatsink core 30. The cable manifold 34 may further comprise a plurality of cable glands 36 circumferentially disposed about all or a portion of the outer cylindrical wall 57. A third endplate, or manifold endplate 38, may be attached to an end of the cable manifold 34 opposite the bottom endplate 32. The manifold endplate 38 may be circular in shape and oriented normal to the central longitudinal axis 40. The manifold endplate 38 may be attached to the bottom of the cable manifold 34 using bolts, screws, threading, welding, or another attachment means.

A cylindrical cable chamber 43 is formed within the cable manifold 34 between the bottom endplate 32 and the manifold endplate 38. As noted above, and as best shown in FIG. 5, bottom end 50 of the heatsink core 30 and bottom end portions 55 of the AC bus bars 26 extending through the bottom endplate 32. Inlets 42 and outlets 44 to the internal coolant passages 35 of the heatsink core 30 may also extend into the cable chamber 43 from the heat sink core 30.

A cable manifold 34 may additionally or alternatively be placed on the top end 11 of the packaged power inverter 10, and attached to the top endplate 12. In such embodiments, additional bus bars may be added that connect to horizontal DC bus bar 18 and extend into the cable manifold 34. In other embodiments, the additional bus bars may connect directly to the capacitors 16.

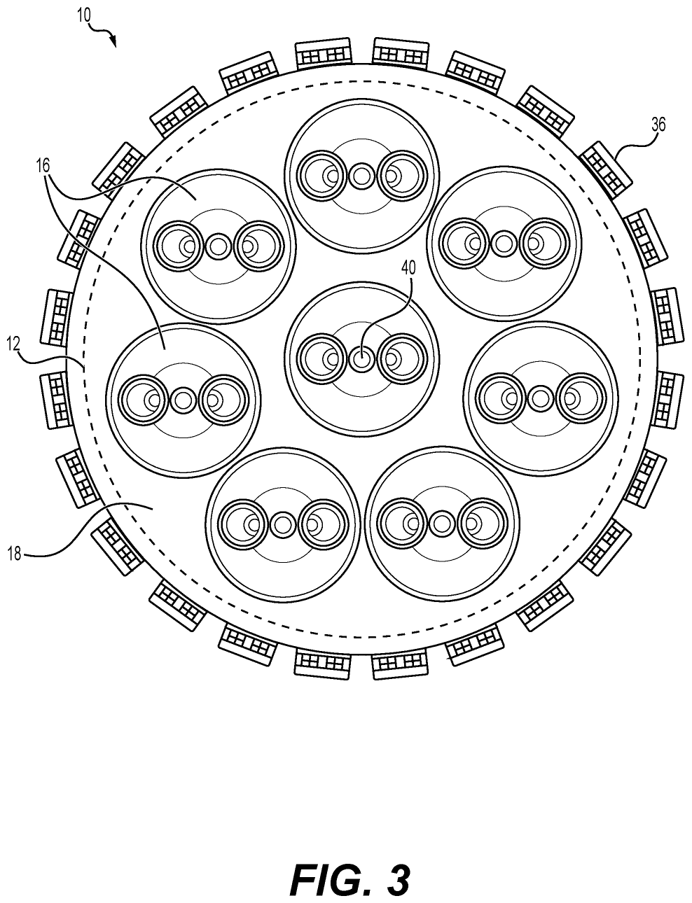

FIG. 3 is a cross sectional view of a packaged power inverter 10 at section 3-3 of FIG. 1, according to an example embodiment. The capacitors 16 may be positioned axially above the heatsink core 30 and between the top endplate 12 and the horizontal DC bus bar 18. Accordingly, the horizontal DC bus bar 18 axially separates the heatsink core 30 from the plurality of capacitors 16. Further, capacitors 16 may be organized radially symmetrically about the central longitudinal axis 40 (extending out of the page in FIG. 3). The capacitors 16 may be further organized in radial layers, such that each radially outer layer encompasses radially inner layers. For example, as shown in FIG. 3, one capacitor 16 forms a radially inner layer, and six capacitors 16 form a radially outer layer. The capacitors 16 may have terminals that connect the capacitors 16 to the horizontal DC bus bar 18 and allow electricity to flow between the horizontal DC bus bar 18 and the capacitors 16.

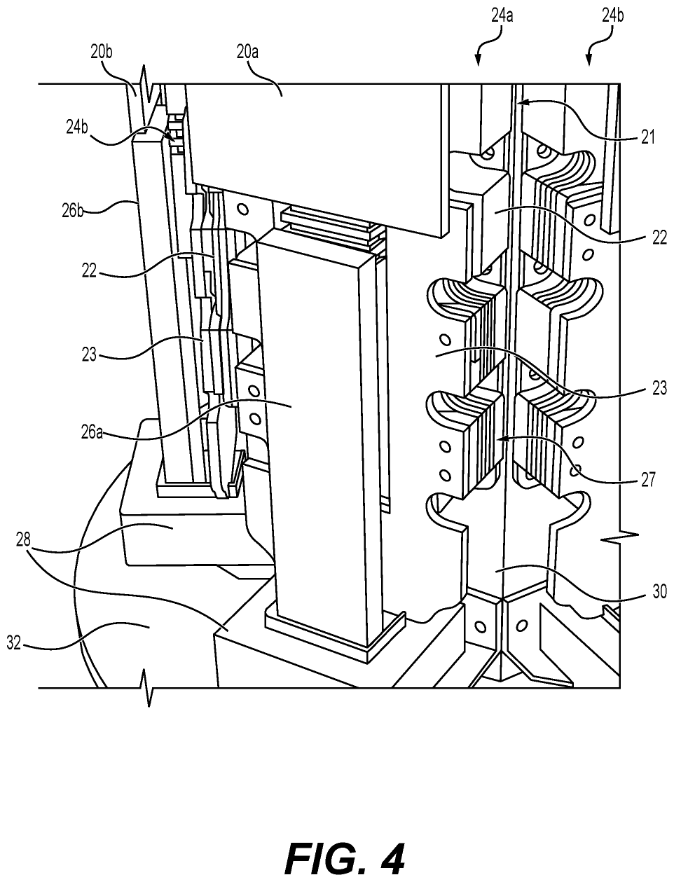

FIG. 4 is a close up side view of a packaged power inverter 10, according to an example embodiment. The gate drivers 23 may be form a “U” shape around the AC end 27 of the electronic modules 24, and connect to both the AC end 27 and the DC end 21 of the electronic modules 24. The gate drivers 23 control the flow of electricity through the IGBT modules 22 according to an input from the external controller (not show). In other embodiments, the gate drivers 23 may have a different shape, and may connect to the electronic modules 24 at different positions.

Depending on the inputs from the controller, the electronic modules 24 function as either power rectifiers or power inverters. In the example embodiment shown in FIG. 4, half of the electronic modules 24 of packaged power inverter 10 may function as power rectifiers (rectifier electronic modules 24a), and the other half of the electronic modules 24 of packaged power inverter 10 may function as power inverters (inverter electronic modules 24b). In such embodiments, the rectifier electronic modules 24a may be on every other planar side 31 of the heat sink 30, and the inverter electronic modules 24b may be on the remaining planar sides 31. In other embodiments, different numbers and sequences of rectifier electronic modules 24a and inverter electronic modules 24b may be used.

The AC bus bars 26 may transfer AC current to or from the AC end 27 of the electronic modules 24 depending on the function of the electronic modules 24, as determined by the controller and gate drivers 23. The AC bus bars 26 attached to rectifier electronic modules 24a may be referred to as rectifier AC bus bars 26a, and AC bus bars attached to inverter electronic modules 24b may be referred to as inverter AC bus bars 26b. A current sensor 28 may be attached to or encircle the AC bus bars 26 longitudinally between the electronic modules 24 and the bottom endplate 32, and may measure the amount of current passing through the AC bus bars 26 and communicate that information to the controller.

The vertical DC bus bars 20 may transfer DC current to or from the DC end 21 of the electronic modules 24 and the horizontal DC bus bar 18 depending on the function of the electronic modules 24 as determined by the controller and gate drivers 23. The vertical DC bus bars 20 attached to the rectifier electronic modules 24a may be referred to as rectifier vertical DC bus bars 20a, and the vertical DC bus bars attached to the inverter electronic modules 24b may be referred to as inverter vertical DC bus bars 20b.

FIG. 5 is a cross sectional view of a packaged power inverter 10 at section 5-5 of FIG. 1, according to an example embodiment. Within the cylindrical cable chamber 43, a control port 45 may be attached to the bottom face 39 of the heat sink 30. The control port 45 may couple the external controller to the electronics of packaged power inverter 10 (e.g., electronic modules 24 and current sensors 28). For example, control port may be connected to the electronic modules 24 and current sensor 28 by wires running through the central opening 33 of the heatsink core 30 and exiting through the planar sides 31 of the heatsink core. The control port 45 may also be connected to control electronics within the central opening 33 of the heatsink core 30. In example embodiments, the control port 45 may be bolted, screwed, welded, glued, or otherwise attached to the bottom face 39. The control port may be a 70 pin connector, or any other suitable port.

External power components may be connected to the packaged inverter 10 by inserting cables (not shown) through the cable glands 36. For example, a controller cable (not shown) can extend through a cable gland 36 and connect to control port 45. Further, power cables (not shown) may extend through cable glands 36 and connect to the bottom end portions 55 of AC bus bars 26 within the cylindrical cable chamber 43. A first set of power cables or wires may connect an input source of AC current to the rectifier AC bus bars 26a. A second set of wires may connect a load to the inverter AC bus bars 26b. The plurality of cable glands 36 allows cables to be inserted into the cable manifold 34 at a multitude of desired trajectories. In some embodiments, the external components connected to the packaged power inverter may connect to every cable gland 36 and AC bus bar 26. In other embodiments, the external components may connect to a subset of the cable glands 36 and the AC bus bars 26.

In some embodiments, an AC source, such as a generator (not shown), may be electrically connected to the packaged power inverter 10 through the cable glands 36 on the cable manifold 34. The AC source may be electrically connected to some or all of the rectifier AC bus bars 26a. An AC load, such as an electric motor, may be connected to one or more of the inverter AC bus bars 26b through the cable glands 36 in the cable manifold 34. In further embodiments, a DC source or load, such as a battery, may be electrically connected to the packaged power inverter 10. In some embodiments, the DC source or load may be electrically connected to one or more of the vertical DC bus bars 20 or the horizontal DC bus bar 18 using cables or additional bus bars. The DC source or load may be electrically connected to the packaged power inverter 10 through the cable manifold 34 at the bottom end 41, a cable manifold at the top end 11, or cable glands 36 on the top endplate 12. In some embodiments, an AC source and a DC load may be connected to the packaged power inverter. In other embodiments, a DC source and an AC load may be electrically connected to the packaged power inverter 10. The sources and loads may be coupled to the packaged power inverter 10, such that they are mounted on either end 11, 41 of the packaged power inverter 10 along the central longitudinal axis 40.

### INDUSTRIAL APPLICABILITY

The disclosed aspects of the packaged power inverter 10 of the present disclosure may be used to isolate and/or provide desirable AC current to a load. The packaged power inverter 10 provides a system by which an input AC voltage or current having an input frequency is transformed into a desired output AC voltages or current having a desired output frequency for use in an electrically powered device.

The modular design may also allow components to be easily accessed and swapped. For example, the capacitance may be increase by simply switching to a longer cylindrical outer housing 14 and switching to longer capacitors 16. The internal components are scalable such that a variable number of internal components may be used within a given cylindrical outer housing 14. Moreover, the packaged power inverter 10 provides flexible mounting options, such that it may be joined with other packaged power inventers or attached to an electric motor or generator. The symmetrical layout of the packaged power inverter 10 aides in distributing the thermal gradient and provides electrical symmetry, which may aide in dynamic current sharing and loss distribution.

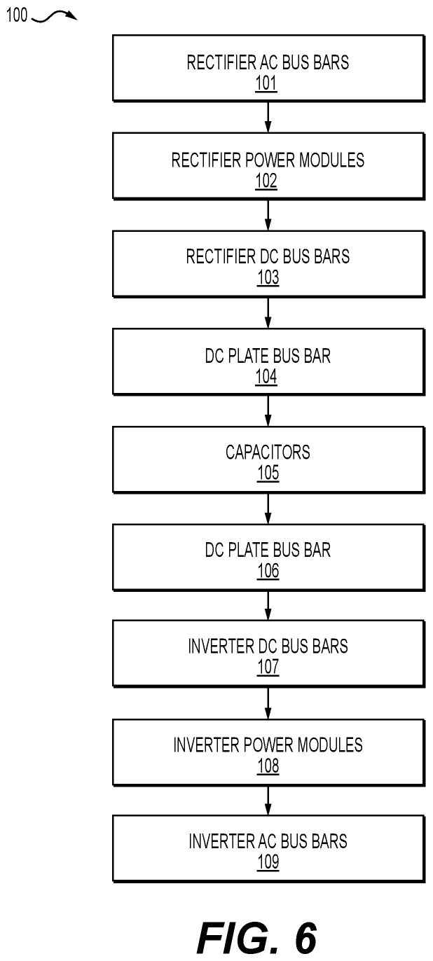

FIG. 6 provides a flowchart 100 depicting the flow of power through the system, according to an example embodiment. Although those skilled in the art will understand AC current to have a bi-directional flow, for explanatory purposes, AC currents will be described as moving in a single direction from input to output. In step 101, an input AC current enters the rectifier AC bus bars 26a from a power cable or wire extending through the cable manifold 34 from an outside power source. In step 102, the input AC current transfers from the rectifier AC bus bars 26a to the rectifier electronic modules 24a, wherein the input AC current is transformed into a DC current that may have ripples. In step 103, the DC current with ripples exits the rectifier electronic modules 24a and enters the rectifier vertical DC bus bars 20a. In step 104, the current transfers from the rectifier vertical DC bus bars 20a to the horizontal DC bus bar 18. From the horizontal DC bus bars 18, a portion of the current may enter the capacitors 16 at step 105. The capacitors 16 provide a stiff DC source for the inverter or rectifier operations. At step 107, a stiff DC current is transferred to the inverter vertical DC bus bars 20b. At step 108, the stiff DC current enters the inverter electronic modules 24b, wherein the smoothed DC current is transformed into an output AC current having a desired waveform. At step 109, the output AC current is transferred to the inverter AC bus bars 26b, which are connected to output cables or wires in cable manifold 34 that carry the output AC current to the load.

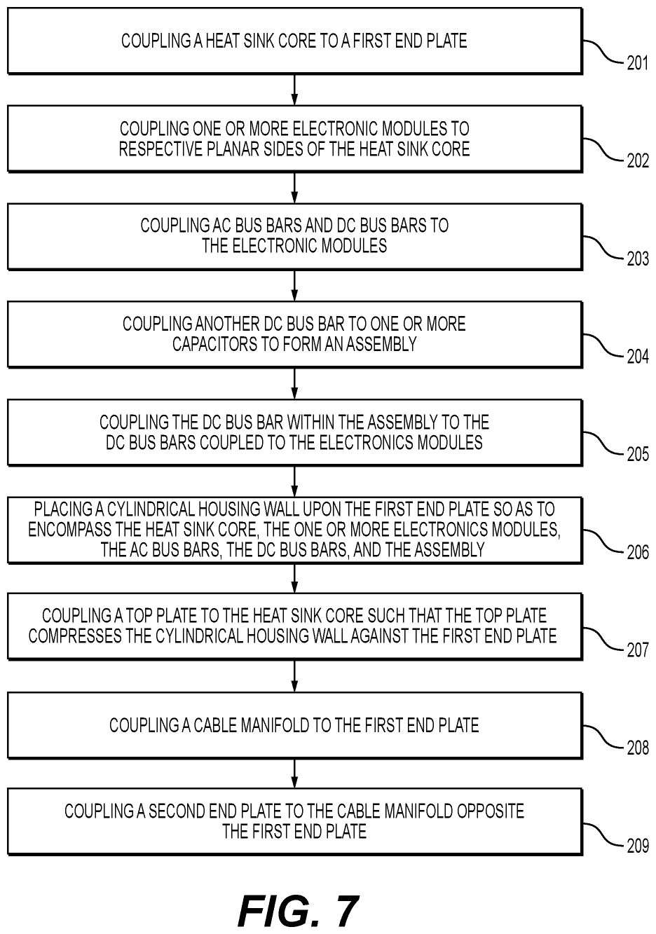

FIG. 7 is a flowchart depicting an example method for assembling the packaged power inverter 10. At step 201, the heat sink core 30 may be coupled to the bottom endplate 32. At step 202, the electronic modules 24 may be coupled to the respective planar sides 31 of the heat sink core 30. At step 203, the AC bus bars 26 and vertical DC bus bars 20 are coupled to the electronic modules 24. At step 204, the horizontal DC bus bar 18 is coupled to one or more capacitors 16 to form an assembly. At step 205, the horizontal DC bus bar 18 within the assembly is coupled to the vertical DC bus bars 20 coupled to the electronics modules 24. Additional supports may also be added between the top face 37 of the heat sink core 30 and the horizontal DC bus bar 18 within the assembly. At step 206, the cylindrical housing wall 15 is placed upon the bottom endplate 32 so as to encompass the heat sink core 30, the one or more electronics modules 24, the AC bus bars, the vertical DC bus bars 20, and the assembly. O-rings may be placed between the cylindrical housing wall 15 and the bottom endplate 32 to provide a seal between the two. At step 207 the top endplate 12 may be coupled to the top face 37 of the heat sink core 30, for example, by using a bolt extending between the two through gaps and passages within the capacitors 16 and horizontal DC bus bar 18. The coupling of the top endplate 12 to the heat sink core 30 may compresses the top endplate 12 against the cylindrical housing wall 15, securing the cylindrical housing wall 15 against the bottom endplate 32. In some embodiments, as shown at step 208, the cable manifold 34 may then be coupled to the bottom endplate 32, and then, as shown in step 209, the cable manifold endplate 38 may be coupled to the cable manifold opposite the bottom endplate 32.

The packaged power inverter 10 may provide a simplified and scalable packaging means for power inverters. For example, the capacitance of the packaged power inverter 10 may be increased by replacing a first set of capacitors 16 with a second set of longer capacitors 16, and replacing the cylindrical outer housing 15 with a longer cylindrical outer housing 15. The modular design also allows for the packaged power inverter to be easily integrated with a similarly-shaped electric motor, as well as an electric generator. Moreover, multiple packaged power inverters 10 may be stacked end to end in order to transform the power produced by a motor and stored by a generator. In particular embodiments, multiple heat sink cores 30 may be joined to a shared capacitor assembly.

The packaged power inverter 10 may also provide desirable performance characteristics and operational aspects. For example, the geometric shape of the heat sink core 30 combined with the geometric arrangement of the electronic modules 24 may assist in providing desirable uniform power density. The geometric shape combined with the placement of the electronic modules 24 on a radially outer surface of the heat sink core 30 may aid in evenly distributing thermal energy while maintaining electrical symmetry and a compact packaging. The placement of the capacitors 16 above the heatsink may allow for a variety of size, types, and arrangements of capacitors 16, and may allow the capacitors 16 to be easily accessed for repairs or replacement. Further, the packaged power inverter 10 allows for a sealed cable manifold 34 that can accommodate cable connections in a multitude of directions.

It will be apparent to those skilled in the art that various modifications and variations can be made to the disclosed system without departing from the scope of the disclosure. Other embodiments of the system will be apparent to those skilled in the art from consideration of the specification and practice of the system disclosed herein. It is intended that the specification and examples be considered as exemplary only, with a true scope of the disclosure being indicated by the following claims and their equivalents.

What is claimed is:

1. A packaged power inverter, comprising:
a cylindrical outer housing having a central longitudinal axis;
a heatsink core located within the housing and having a longitudinal axis aligned with the longitudinal axis of the outer housing, the heatsink core including a plurality of outer planar surface portions;
a plurality of electronic modules, each being coupled to one of the plurality of planar surface portions;
a plurality of AC bus bars, each being coupled to one of the plurality of planar surface portions;
a plurality of capacitors located within the outer housing; and
a plurality of DC bus bars located within the outer housing.

2. The packaged power inverter of claim 1, wherein the capacitors are spaced axially from the heatsink core.

3. The packaged power inverter of claim 2, wherein at least one of the DC bus bars is plate-shaped and located axially between the heatsink core and the plurality of capacitors.

4. The packaged power inverter of claim 1, wherein the plurality of electronic modules, the plurality of AC bus bars, and the plurality of DC bus bars are symmetrically organized about the heatsink core and aligned with a respective one of the plurality of planar surface portions.

5. The packaged power inverter of claim 1, further including a cable manifold having a portion that is axially spaced from the heatsink core.

6. The packaged power inverter of claim 5, wherein the cable manifold forms a cylindrical cable chamber between a first endplate and a second, manifold endplate opposite the first endplate, and a plurality of cable glands are radially orientated about an outer wall of the cylindrical cable chamber.

7. The packaged power inverter of claim 6, wherein the plurality of AC bus bars extend through openings in the first endplate and into the cylindrical cable chamber.

8. The packaged power inverter of claim 1, wherein the heatsink core is formed of extruded aluminum and includes coolant passages.

9. The packaged power inverter of claim 1, wherein control electronics are located within a central opening in the heatsink core.

10. The packaged power inverter of claim 1, wherein the planar surface portions form one of a octagon, hexagon, or triangle outer shape of the heatsink core.

11. The packaged power inverter of claim 1, wherein the electronic modules are directly coupled to the plurality of planar surface portions of the heatsink core.

12. The packaged power inverter of claim 1, wherein the plurality of AC bars are directly coupled to a radially outer surface of a corresponding electronic module, and the electronic modules include an insulated-gate bipolar transistor (IGBT) module and a gate driver.

13. The packaged power inverter of claim 1, wherein the capacitors are located axially between an endplate of the cylindrical outer housing, and a DC bus bar.

14. The packaged power inverter of claim 1, wherein a cylindrical housing wall of the cylindrical outer housing is a single aluminum tube.

15. The packaged power inverter of claim 1, further including a current sensor attached to the AC bus bars.

16. A packaged power inverter, comprising:
a cylindrical outer housing having a central longitudinal axis;
a heatsink core located within the housing and having a longitudinal axis aligned with the longitudinal axis of the outer housing, the heatsink core including a plurality of outer planar surface portions;
a plurality of electronic modules, each being coupled to one of the plurality of planar surface portions;
a plurality of AC bus bars, each associated with one of the plurality of electronic modules, and located radially outside a respective electronic module;
a plurality of capacitors located within the outer housing;
a plurality of DC bus bars located within the outer housing; and
a DC bus bar located axially between the heatsink core and the plurality of capacitors.

17. The packaged power inverter of claim 16, further including a plurality of DC bus bars, each associated with one of the plurality of electronic modules, and located radially outside a respective electronic module.

18. The packaged power inverter of claim 16, wherein the capacitors are spaced axially from the heatsink core.

19. A method of assembling a packaged power inverter, the method comprising:
coupling a heat sink core to a first endplate;
coupling one or more electronic modules to respective planar sides of the heat sink core;
coupling AC bus bars and DC bus bars to the electronic modules;
coupling another DC bus bar to one or more capacitors to form an assembly;
coupling the DC bus bar within the assembly to the DC bus bars coupled to the electronics modules;
placing a cylindrical housing wall upon the first endplate so as to encompass the heat sink core, the one or more electronics modules, the AC bus bars, the DC bus bars, and the assembly; and
coupling a top plate to the heat sink core such that the top plate compresses the cylindrical housing wall against the first endplate.

20. The method of assembling a packaged power inverter of claim 19, the method further comprising:
coupling a cable manifold to the first endplate, and
coupling a second endplate to the cable manifold opposite the first endplate.
